(19) United States
(12) Patent Application Publication
(10) Pub. No.: US 2023/0324819 A1
(43) Pub. Date: Oct. 12, 2023

(54) LAMINATE, DEVICE USING THE SAME, AND PRODUCTION METHODS THEREOF

(71) Applicants: Hidetoshi KAMI, Shizuoka (JP); Ryota INOUE, Shizuoka (JP); Keisuke SHIMOYAMA, Shizuoka (JP); Ryohta TAKAHASHI, Shizuoka (JP)

(72) Inventors: Hidetoshi KAMI, Shizuoka (JP); Ryota INOUE, Shizuoka (JP); Keisuke SHIMOYAMA, Shizuoka (JP); Ryohta TAKAHASHI, Shizuoka (JP)

(21) Appl. No.: 18/020,641

(22) PCT Filed: Jul. 29, 2021
(86) PCT No.: PCT/JP2021/027993

§ 371 Date: Feb. 10, 2023

(30) Foreign Application Priority Data
Aug. 20, 2020 (JP) 2020-139557
Jun. 29, 2021 (JP) 2021-107600

(51) Int. Cl. G03G 5/147

(52) U.S. Cl. CPC G03G 5/14773; G03G 5/14704

(57) ABSTRACT

To provide a laminate including: a layer (1) including an organic material; a layer (2) including a siloxane compound and metal oxide, where the layer (2) is in contact with the layer (1); and a layer (3) including the metal oxide, where the layer (3) is in contact with the layer (2).

### TECHNICAL FIELD

The present disclosure relates to a laminate, a device using the laminate, and production methods thereof.

### BACKGROUND ART

In the art, the aerosol deposition method (AD method) has been known as a method for forming a ceramic layer on a surface of a base at room temperature. According to the AD method, a metal material, such as stainless steel and iron, or glass is used as a base to which ceramic coating is applied. Recently, a ceramic coating technique on a resin material has been developed (see PTL 1 and PTL 2).

The ceramic coating applied to the resin material is intended to be hard coating on a resin case or window frame, it is desired that adhesion of the ceramic material to the resin base is sufficient. Moreover, the ceramic coating film is desired to have toughness that is matched to properties of the bulk ceramic. When such ceramic coating technique to the resin material is applied to industrial products, it is desired that adhesion and toughness of a coating surface are further enhanced.

When the resin material is a surface material of an organic electronic device, such as OPC, OLED, and OPV, it is not acceptable that ceramic coating applied to the base adversely affects functions of the device. Moreover, it is also not acceptable that the coated ceramic material is easily detached from the base.

As the most matured organic electronic device, OPC can be named. Since OPC has great freedom in designing and can be produced with simple equipment, OPC occupies nearly 100% of the entire photoconductors available on the market. However, a lifespan of the OPC is significantly shorter than an inorganic photoconductor, such as an amorphous silicon photoconductor. Due to the short lifespan thereof, a large number of OPCs are produced and discarded.

In recent years, changes in climate, such as a disaster that generally happens once every 10 years, are normalized. The amount of CO₂ released, which can be a cause of the above-mentioned problem, is a significant social problem to be solved. Since a device is fragile, a release amount of CO₂ released by disposal and production of a significant amount of devices due to fragility of devices cannot be ignored any longer. Therefore, application of a technology for increasing durability and extending lifespan on other devices is desired.

### CITATION LIST

### Patent Literature

PTL 1: International Patent Publication No. WO 2017/199968
PTL 2: International Patent Publication No. WO 2018/194064

### SUMMARY OF INVENTION

### Technical Problem

An object of the present disclosure is to provide a laminate that includes a layer including an organic material, a layer including a siloxane compound and metal oxide, and a layer including metal oxide, where the layer including metal oxide has high strength, and the laminate has excellent durability.

### Solution to Problem

According to one aspect of the present disclosure, a laminate includes a layer (1) including an organic material, a layer including siloxane compound and metal oxide (2), and a layer (3) including the metal oxide. The layer (2) is in contact with the layer (1). The layer (3) is in contact with the layer (2).

### Advantageous Effects of Invention

According to the present disclosure, it is possible to provide a laminate that includes a layer including an organic material, a layer including a siloxane compound and metal oxide, and a layer including metal oxide, where the layer including metal oxide has high strength, and the laminate has excellent durability.

### BRIEF DESCRIPTION OF DRAWINGS

FIG. 1 is a schematic cross-sectional view illustrating one embodiment of the device (photoconductor) of the present disclosure.

FIG. 2 is a schematic cross-sectional view illustrating another embodiment of the device (photoconductor) of the present disclosure.

FIG. 3 is a schematic cross-sectional view illustrating another embodiment of the device (photoconductor) of the present disclosure.

FIG. 4 is a schematic cross-sectional view illustrating another embodiment of the device (photoconductor) of the present disclosure.

FIG. 5 is a schematic cross-sectional view illustrating another embodiment of the device (photoconductor) of the present disclosure.

FIG. 6 is a schematic cross-sectional view illustrating another embodiment of the device (photoconductor) of the present disclosure.

FIG. 7 is a schematic view illustrating an aerosol deposition device.

FIG. 8 is a schematic cross-sectional view illustrating one embodiment of the device (organic EL element) of the present disclosure.

FIG. 9 is a view illustrating one embodiment of the device (image forming apparatus) of the present disclosure.

FIG. 10 is an example of a cross-sectional photograph illustrating the laminate of the present disclosure.

FIG. 11 is an example illustrating a distribution of carbon on a cross-section of the laminate of the present disclosure.

FIG. 12 is an example illustrating a distribution of silicon on a cross-section of the laminate of the present disclosure.

FIG. 13 is an example illustrating a distribution of aluminium on a cross-section of the laminate of the present disclosure.

FIG. 14 is an example illustrating a state of the undercoat layer on the cross-section of the laminate.

### DESCRIPTION OF EMBODIMENTS

Embodiments of the present disclosure will be more specifically described hereinafter.

The laminate of the present disclosure include a layer (1) including an organic material, a layer (2) including a siloxane compound and metal oxide, where the layer (2) is in contact with the layer (1), and a layer (3) including the metal oxide, where the layer (3) is in contact with the layer (2).

When ceramic coating is applied onto an organic material by the AD method, in addition to suppression of erosion of the organic material, adhesion between the organic material and the ceramic material is important. The adhesion often relies on anchoring. The anchoring is a phenomenon where the ceramic material penetrates into the base to form irregular shapes at the interface to function as an anchor. The strength derived from the ceramic may affect the adhesion.

When the direct AD method is applied to an organic material, only erosion is progressed by impacts applied by the aerosol powder. Therefore, desirable is to dispose an undercoat layer on which the deposited aerosol powder is grown.

A siloxane compound is preferably used for the undercoat layer. The materials used in Examples of the present specification are effective for accelerating the deposition of the aerosol powder.

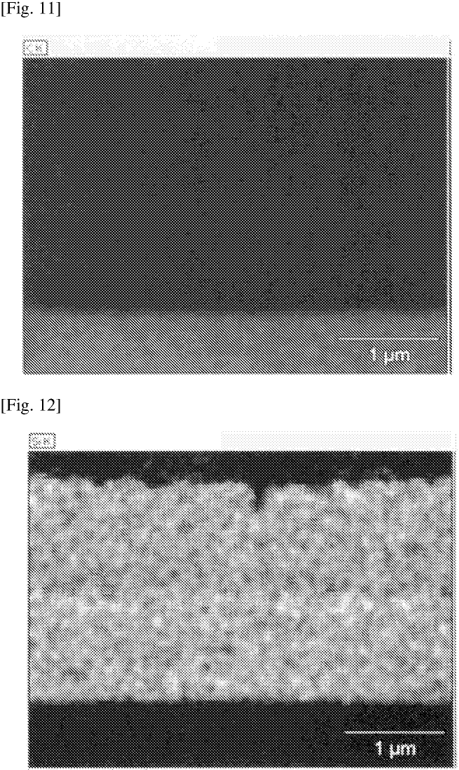

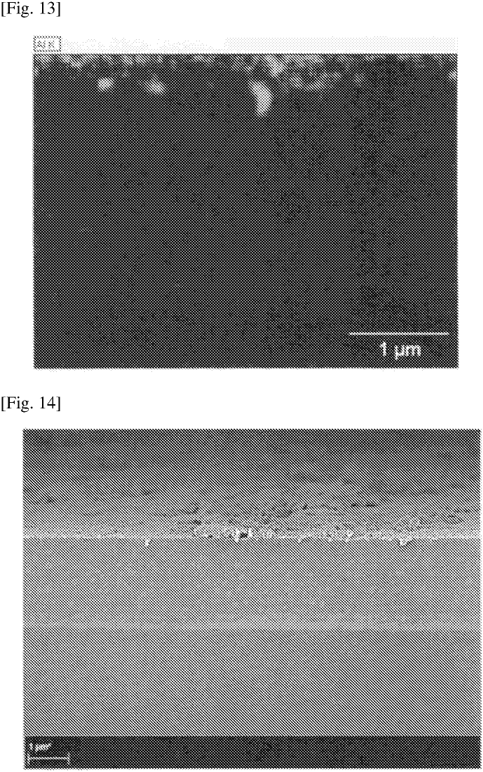

When a device is put into practical use, improvement of the adhesion is particularly important. In order to achieve the improvement of the adhesion, it has been found that formation of slight irregularities, so-called anchoring, over the entire undercoat layer is effective. The present invention has been accomplished base on the above-mentioned insight. FIG. 10 is a cross-section photograph depicting an example of the above-described embodiment captured by an electron microscope. On an OPC that is an organic device, an undercoat layer and a ceramic layer that is like a thin film are formed. The results of the elemental analysis performed on the target of FIG. 10 by an energy dispersive X-ray spectrometer (EDS) are depicted in FIGS. 11 to 13. In FIGS. 11 to 13, distributions of carbon, silicon, and aluminium are presented, respectively. The carbon is derived from the organic material present at the surface of the OPC. The silicon is derived from the siloxane compound contained in the coating material of the undercoat layer. The aluminium is derived from copper aluminate that is a material of the ceramic layer formed by the AD method. It can be understood that the aluminium is distributed over the entire undercoat layer. The distribution of the above-mentioned elements can be also observed by adjusting the observation conditions of the electron microscopic photograph. FIG. 14 is such an example, and it can be observed that the material of the ceramic layer is locally present at the interface between the undercoat layer and the organic material.

The laminate of the present disclosure is suitably used for devices, such as a photoelectric conversion element, an organic photoconductor (OPC), an image forming apparatus, an organic EL element(OLED), and an organic photovoltaic (OPV) device, or image forming methods.

As described above, the laminate of the present disclosure includes a layer (1) including an organic material, a layer (2) including a siloxane compound and metal oxide, where the layer (2) is in contact with the layer (2), and a layer (3) including the metal oxide, where the layer (3) is in contact with the layer (2). Among the above-listed examples, for example, an OPC includes a layer (1) including an organic material serving as a photoelectric conversion layer, disposed on a support, a layer (2) including a siloxane compound and metal oxide serving as an undercoat layer, and a layer (3) including the metal oxide serving as a ceramic film.

First, an OPC (may be referred to as a photoconductor of the present disclosure hereinafter) will be described as an application example of the laminate of the present disclosure, but the present disclosure is not limited to the embodiments described below.

### Photoconductor

In the photoconductor, a photoelectric conversion layer is preferably formed as a photoconductive layer, and a support is preferably formed as a conductive support. Moreover, the photoconductor is preferably an organic photoconductor.

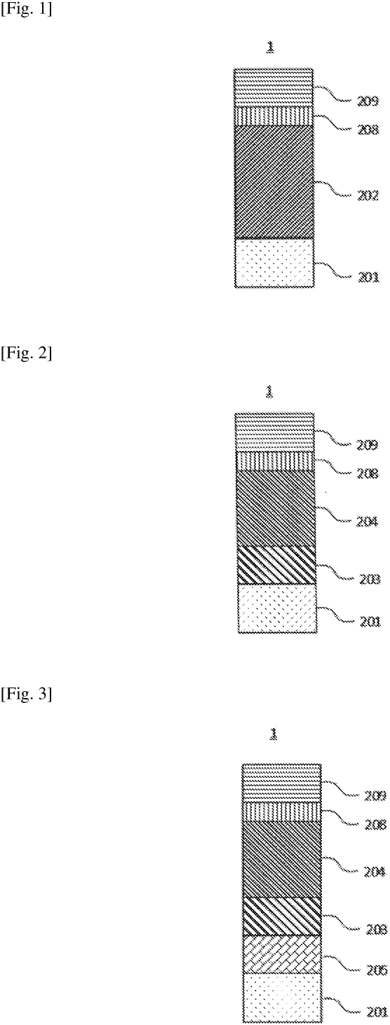

FIG. 1 is a schematic cross-sectional view illustrating one embodiment of the device (photoconductor) of the present disclosure.

In FIG. 1, the photoconductor 1 includes a photoconductive layer 202 (the layer (1)) disposed on a conductive support 201, an undercoat layer 208 (the layer (2)) disposed on the photoconductive layer 202, and a surface layer 209 (the layer (3)) disposed on the undercoat layer 208. As described above, in the photoconductor 1, the surface layer 209 is a ceramic film, and the undercoat layer 208 includes a siloxane compound.

FIG. 2 is a schematic view illustrating another embodiment of the device (photoconductor) of the present disclosure.

The photoconductor 1 of FIG. 2 is a function-separation type photoconductor where the photoconductive layer includes a charge-generating layer (CGL) 203 and a charge-transporting layer (CTL) 204.

FIG. 3 is a schematic cross-sectional view illustrating yet another embodiment of the device (photoconductor) of the present disclosure.

The photoconductor 1 of FIG. 3 is the functional-separation type photoconductor as illustrated in FIG. 2, except that an undercoat layer 205 is disposed between the support 201 and the charge-generating layer (CGL) 203.

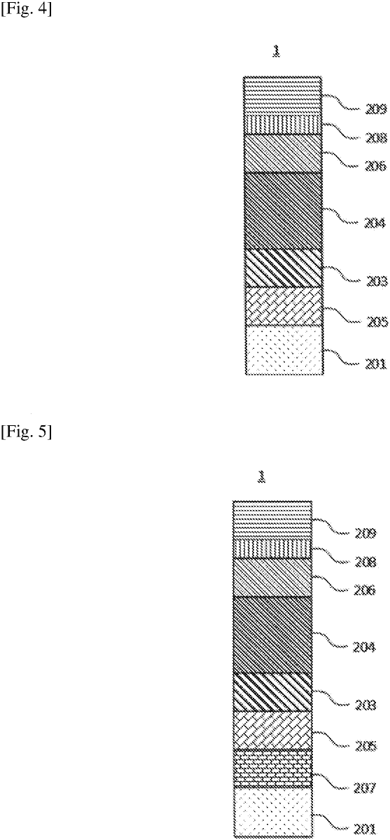

FIG. 4 is a schematic cross-sectional view illustrating yet another embodiment of the device (photoconductor) of the present disclosure.

The photoconductor 1 of FIG. 4 is the function-separation type photoconductor as illustrated in FIG. 3, except that a protective layer 206 is disposed on the charge-transporting layer (CTL) 204.

FIG. 5 is a schematic cross-sectional view illustrating yet another embodiment of the device (photoconductor) of the present disclosure.

The photoconductor 1 of FIG. 5 is the function-separation type photoconductor as illustrated in FIG. 4, except that an intermediate layer 207 is disposed between the support 201 and the undercoat layer 205.

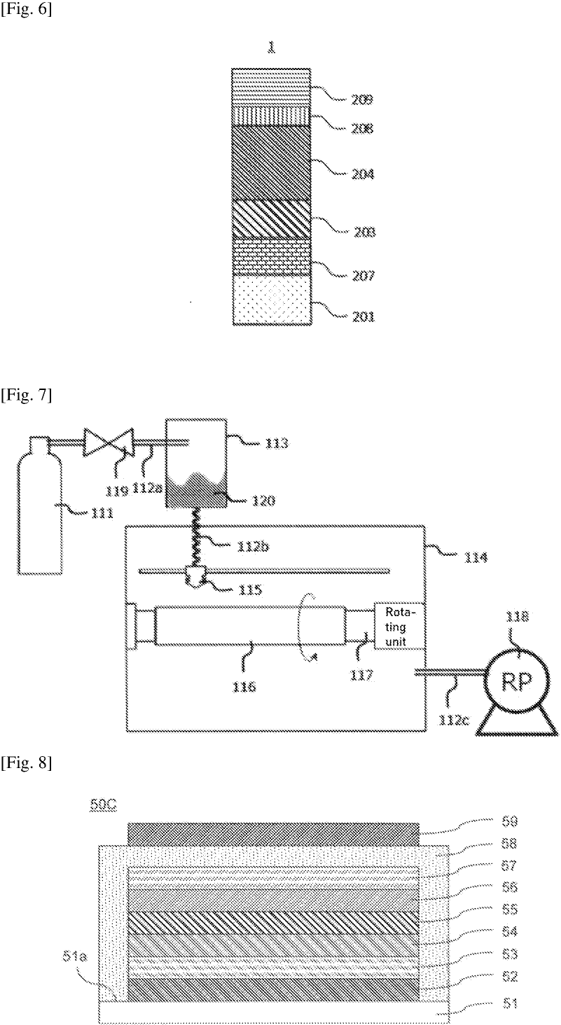

The device (photoconductor) of the present disclosure is not limited to the embodiments described above. For example, the device (photoconductor) of the present disclosure may be a photoconductor 1, where an intermediate layer 207, a charge-generating layer 203, a charge-transporting layer 204, an undercoat layer 208, and a surface layer 209 are disposed on a conductive support 201 in this order, as illustrated in FIG. 6.

The device (photoconductor) of the present disclosure has excellent chargeability an organic photoconductor has, and has excellent abrasion resistance matched with abrasion resistance of an in organic photoconductor, because the surface layer of the device is a ceramic film. Moreover, the device has excellent gas barrier properties because the undercoat layer includes a siloxane compound. Therefore, the device achieves excellent image quality as well has having excellent durability.

Since the photoconductor includes the siloxane compound-containing undercoat layer, the photoconductor has high gas permeability, and the photoconductive layer having low strength can be covered with a dense inorganic film to enhance gas barrier properties. In addition, the undercoat layer has extremely high mechanical strength compared with an organic material, to significantly increase abrasion resistance of the photoconductor.

### <Photoconductive Layer>

The photoconductive layer may be a multi-layer photoconductive layer or a single-layer photoconductive layer.

### <<Multi-layer Photoconductive Layer>>

As described above, the multi-layer photoconductive layer includes at least a charge-generating layer and a charge-transporting layer in this order. The multi-layer photoconductive layer may further include other layers according to the necessity.

### -Charge-generating Layer-

The charge-generating layer includes at least a charge-generating material, and may further include a binder resin, and other components according to the necessity.

The charge-generating material is not particularly limited, and may be appropriately selected depending on the intended purpose. An inorganic material or an organic material may be used as the charge-generating material. Examples thereof include crystalline selenium, amorphous-selenium, selenium-tellurium, selenium-tellurium-halogen, a selenium-arsenic compound, a phthalocyanine-based pigment (e.g., metal phthalocyanine, and metal-free phthalocyanine), and an azo pigment including any of a carbazole skeleton, a triphenylamine skeleton, a diphenylamine skeleton, or a fluorenone skeleton. The above-listed examples may be used alone or in combination.

The binder resin is not particularly limited, and may be appropriately selected depending on the intended purpose. Examples thereof include a polyvinyl butyral resin, and a polyvinyl formal resin. The above-listed examples may be used alone or in combination.

Examples of a method for forming the charge-generating layer include a vacuum film formation method, and casting of a solution dispersion system.

Examples of an organic solvent used for a coating liquid of the charge-generating layer include methyl ethyl ketone, and tetrahydrofuran. The above-listed examples may be used alone or in combination.

The average thickness of the charge-generating layer is typically preferably from 0.01 µm through 5 µm, and more preferably from 0.05 µm through 2 µm.

### -Charge-transporting Layer-

The charge-transporting layer is a layer configured to retain electric charge, and transfer the charge generated and separated in the charge-generating layer as a result of exposure to combine with the retained electric charge. In order to retain the electric charge, it is desired that the charge-transporting layer has high electric resistance. In order to obtain high surface potential with the retained electric charge, it is desired that the charge-transporting layer has low dielectric constant, and excellent charge mobility.

The charge-transporting layer includes at least a charge-transporting material or a sensitizing dye, and may further include a binder resin, and other components according to the necessity.

Examples of the charge-transporting material include a hole-transporting material, an electron-transporting material, and a charge-transporting polymer material. Examples of the electron-transporting material (electron-accepting material) include 2,4,7-trinitro-9-fluorenone, and 1,3,7-trinitrodibenzothiophene-5,5-dioxide. The above-listed examples may be used alone or in combination.

Examples of the hole-transporting material (electron-donating material) include a triphenylamine derivative, and an α-phenylstilbene derivative. The above-listed examples may be used alone or in combination.

Examples of the charge-transporting polymer material include materials having the following structures. Examples thereof include a polysilylene polymer and a polymer having a triarylamine structure.

Examples of the binder resin include a polycarbonate resin, and a polyester resin. The above-listed examples may be used alone or in combination.

The charge-transporting layer may include a copolymer of a crosslinked binder resin and a crosslinked charge-transporting material.

Examples of the sensitizing dye include known metal complex compounds, a coumarin compound, a polyene compound, an indoline compound, and a thiophene compound.

The charge-transporting layer can be formed by dissolving or dispersing the charge-transporting material or sensitizing dye, and the binder resin in an appropriate solvent to prepare a coating liquid, and applying and drying the coating liquid.

The charge-transporting layer may include, in addition to the charge-transporting material or sensitizing dye and the binder resin, an appropriate amount of additives, such as a plasticizer, an antioxidant, and a leveling agent.

The average thickness of the charge-transporting layer is preferably from 5 µm through 100 µm. A reduction in a thickness of the charge-transporting layer has been attempted in order to meet the current demands for high image quality. In order to achieve high image quality of 1,200 dpi or greater, the average thickness thereof is more preferably from 5 µm through 30 µm.

### <<Single-layer Photoconductive Layer>>

The single-layer photoconductive layer includes a charge-generating material, a charge-transporting material, and a binder resin, and may further include other components according to the necessity.

As the charge-generating material, the charge-transporting material, and the binder resin, those used in the multi-layer photoconductive layer can be used.

When the single-layer photoconductive layer is disposed by casting, in most of cases, the single-layer photoconductive layer can be formed by dissolving or dispersing the charge-generating material and low molecular weight and high molecular weight charge-transporting materials in an appropriate solvent to prepare a coating liquid, and applying and drying the coating liquid. Moreover, the single-layer photoconductive layer may optionally further include a plasticizer, and a binder resin.

As the binder resin, a binder resin that is the same as the binder resin of the charge-transporting layer may be used, or a mixture of binder resins the same as the binder resins of the charge-generating layer may be used.

The average thickness of the single-layer photoconductive layer is preferably from 5 µm through 100 µm, and more preferably from 5 µm through 50 µm.When the average thickness of the single-layer photoconductive layer is less than 5 µm, resulting chargeability may be low. When the average thickness thereof is greater than 100 µm, resulting sensitivity may be low.

### <Support>

The support may be appropriately selected depending on the intended purpose. For example, a conductive support may be used as the support. The support is preferably a conductor, or a conduction-treated insulator. Examples thereof include: metals, such as Al, and Ni, and alloys thereof; an insulator substrate (e.g., polyester, and polycarbonate) on which a film of metal (e.g., Al) or a conductive material (e.g., In₂O₃, and SnO₂) is formed; a resin base to which conduction is imparted by evenly dispersing carbon black, graphite, metal powder (e.g., Al, Cu, and Ni), or conductive glass powder in the resin; and conduction-treated paper.

A shape of the support is not particularly limited. Any of a plate type, a drum type, or a belt type may be used.

A size of the support is not particularly limited and may be appropriately selected depending on the intended purpose.

An undercoat layer may be optionally disposed between the support and the photoconductive layer. The undercoat layer is disposed for the purpose of improving adhesion, preventing moire, improving coatablity of an upper layer, and reducing residual potential.

Generally, the undercoat layer includes a resin as a main component. Examples of the resin include alcohol-soluble resins (e.g., polyvinyl alcohol, copolymer nylon, and methoxymethylated nylon), and curable resins for forming a three-dimensional network structure (e.g., polyurethane, a melamine resin, and an alkyd-melamine resin).

Moreover, powder, such as metal oxide (e.g., titanium oxide, silica, alumina, zirconium oxide, tin oxide, and indium oxide), metal sulfide, and metal nitride may be added to the undercoat layer. The undercoat layer may be formed using an appropriate solvent by a coating method commonly used. The average thickness of the undercoat layer is not particularly limited, and may be appropriately selected depending on the intended purpose. The average thickness thereof is preferably from 0.1 µm through 10 µm, and more preferably from 1 µm through 5 µm.

In the device (photoconductor) of the present disclosure, a protective layer may be disposed on the photoconductive layer for the purpose of protecting the photoconductive layer. Examples of a material used for the protective layer include resins, such as an ABS resin, an ACS resin, an olefin-vinyl monomer copolymer, chlorinated polyether, an aryl resin, a phenol resin, polyacetal, polyamide, polyamideimide, polyacrylate, polyallylsulfone, polybutylene, polybutylene terephthalate, polycarbonate, polyether sulfone, polyethylene, polyethylene terephthalate, polyimide, an acrylic resin, polymethyl pentene polypropylene, polyphenylene oxide, polysulfone, polystyrene, polyarylate, an AS resin, a butadiene-styrene copolymer, polyurethane, polyvinyl chloride, polyvinylidene chloride, and an epoxy resin.

As a formation method of the protective layer, any of methods known in the art, such as dip coating, spray coating, bead coating, nozzle coating, spin coating, and ring coating, may be used.

In the device (photoconductor) of the present disclosure, an intermediate layer may be optionally disposed on the support for the purpose of improving adhesion and charge blocking properties. The intermediate layer generally includes a resin as a main component. Considering the photoconductive layer is applied the intermediate layer with a solvent, the resin is ideally a resin highly insoluble to general organic solvents.

Examples of the resin include water-soluble resins (e.g., polyvinyl alcohol, casein, and sodium polyacrylate), alcohol-soluble resins (e.g., copolymer nylon, and methoxymethylated nylon), and curable resin for forming a three-dimensional network structure (e.g., a polyurethane resin, a melamine resin, a phenol resin, an alkyd-melamine resin, and an epoxy resin).

### <Undercoat Layer>

The undercoat layer is a layer including a siloxane compound. The siloxane compound is a compound obtained by crosslinking an organic silicon compound having a hydroxyl group or a hydrolysable group.

The siloxane compound can enhances gas barrier properties and further improve abrasion resistance, as well as fixing the surface layer formed of a ceramic film on a surface of the photoconductor.

### -Siloxane Compound-

The siloxane compound is obtained by crosslinking an organic silicon compound having a hydroxyl group or a hydrolysable group. The siloxane compound may include a catalyst, a crosslinking agent, organo silica sol, a silane coupling agent, and a polymer (e.g., acrylic polymer), according to the necessity.

The crosslinking is not particularly limited, and may be appropriately selected depending on the intended purpose, but thermal crosslinking is preferable.

Examples of the organic silicon compound having a hydroxyl group or a hydrolyzable group include a compound having an alkoxysilyl group, a partial hydrolyzed condensation product of a compound having an alkoxysilyl group, and a mixture thereof.

Examples of the compound having an alkoxysilyl group include: tetraalkoxy silane, such as tetraethoxy silane; alkyl trialkoxy silane, such as methyl triethoxy silane; and aryl trialkoxy silane, such as phenyl triethoxy silane. Compounds obtained by introducing an epoxy group, a methacryloyl group, or a vinyl group to any of the above-listed compounds may also be used.

The partial hydrolyzed condensation product of the compound having an alkoxysilyl group can be produced by a conventional method where predetermined amounts of water, a catalyst, etc. are added to the compound having an alkoxysilyl group, and the mixture is allowed to react.

Any of commercial products may be used as a raw material of the siloxane compound. Specific examples thereof include GR-COAT (obtained from Daicel Corporation), Glass Resin (obtained from OWENS CORNING JAPAN LLC), Heatless Glass (obtained from OHASHI CHEMICAL INDUSTRIES LTD.), NSC (obtained from TAIMEI CHEMICALS CO., LTD.), undiluted glass solution GO150SX and GO200CL (both obtained from Fine Glass Technologies), and copolymers of an alkoxysilyl compound with an acrylic resin or a polyester resin, such as MKC silicate (obtained from Mitsui Chemicals, Inc.), silicate/acryl varnish XP-1030-1 (obtained from Aica Kogyo Co., Ltd.), X-40-9250 (obtained from Shin-Etsu Chemical Co., Ltd.), and KR-401 (obtained from Shin-Etsu Chemical Co., Ltd.). The raw material of the siloxane compound may be referred to as a curable siloxane resin.

Among the above-listed example, the siloxane compound preferably includes the following structure for improving effects obtainable by the present disclosure

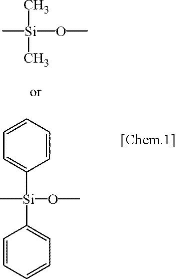

The average thickness of the undercoat layer is preferably 0.01 µm or greater but 4.0 µm or less, more preferably 0.03 µm or greater but 4.0 µm or less, and even more preferably 0.05 µm or greater but 2.5 µm or less. Moreover, the average thickness thereof is also preferably 0.1 µm or greater. The average thickness thereof is particularly preferably 0.01 µm or greater but 2.5 µm or less.

The metal oxide included in the undercoat layer is derived from the aerosol powder from the AD method.

### <Surface Layer>

The surface layer in the device (photoconductor) of the present disclosure is a ceramic film.

The ceramic constituting the ceramic film is typically metal oxide obtained by firing metal.

The ceramic is not particularly limited, and may be appropriately selected depending on the intended purpose. Examples thereof include metal oxide, such as titanium oxide, silica, alumina, zirconium oxide, tin oxide, and indium oxide.

The ceramic preferably include transparent conductive oxide, and the transparent conductive oxide is preferably a ceramic semiconductor. Moreover, the transparent conductive oxide preferably includes delafossite or perovskite. The delafossite preferably includes copper aluminium oxide, copper chromium oxide, and copper gallium oxide. The perovskite is a composite material of an organic compound and an inorganic compound, and can be represented by General Formula (1) below.

$$X α Y β M γ \qquad \text{(General Formula (1)}$$

In General Formula (1) above, the ratio α:β:γ is 3:1:1, and β and γ are each aninteger larger than 1. For example, moreover, X may be a halogen ion, Y may be an alkylamine compound ion, and M may be a metal ion.

### <Ceramic Semiconductor>

The ceramic semiconductor is a ceramic having a partial defect in a typical electron configuration due to oxygen deficiency, and is a collective name of compounds exhibiting conductivity under certain conditions due to the oxygen deficiency of the electron configuration.

In the present disclosure, the surface layer is preferably a metal oxide-containing layer. The metal oxide-containing layer has characteristics that the metal oxide-containing layer exhibits conductivity under certain conditions due to oxygen deficiency of the electron configuration, and is defined as a layer where a ceramic semiconductor component is densely arranged without leaving gaps and the layer does not include an organic compound.

The metal oxide-containing layer preferably includes delafossite. In the present disclosure, moreover, the metal oxide-containing layer preferably has mobility of charge that is holes or electrons.

The charge mobility of the metal oxide-containing layer with the field intensity of 2 × 10⁻⁴ V/cm is preferably 1×10⁻⁶ cm²/Vsec or greater. In the present disclosure, the higher charge mobility is more preferable. A measuring method of the charge mobility is not particularly limited, and may be appropriately selected from general measuring methods depending on the intended purpose. Examples thereof include a method where preparation of a sample and measurement are performed in the manner as described in Japanese Unexamined Patent Application Publication No. 2010-183072. Moreover, the bulk resistance including the metal oxide-containing layer is preferably less than 1 ×10 ¹³Ω.

### -Delafossite-

The delafossite (may be referred to as a “p-type semiconductor,” and “p-type metal compound semiconductor”) is not particularly limited as long as the delafossite has a function as a p-type semiconductor, and may be appropriately selected depending on the intended purpose. Examples thereof include a p-type metal oxide semiconductor, a p-type metal compound semiconductor including monovalent copper, and other p-type metal compound semiconductors.

Examples of the p-type metal oxide semiconductor include CoO, NiO, FeO, Bi₂O₃, MoO₂, MoS₂, Cr₂O₃, SrCu₂O₂, and CaO—Al₂O₃.

Examples of the p-type metal compound semiconductor including monovalent copper include CuI, CuInSe₂, Cu₂O, CuSCN, CuS, CuInS₂, CuAlO, CuAlO₂, CuAlSe₂, CuGaO₂, CuGaS₂, and CuGaSe₂.

Examples of the other p-type metal compound semiconductors include GaP, GaAs, Si, Ge, and SiC. Considering the improvement of the effects of the present disclosure, the delafossite is preferably copper aluminium oxide, and the copper aluminium oxide is more preferably CuAlO₂.

### -Production of Ceramic Film-

A production method (film formation method) of the ceramic film is not particularly limited, and may be appropriately selected from inorganic material film formation methods generally used depending on the intended purpose. Examples thereof include a vapor deposition method, a liquid phase deposition method, and a solid phase deposition method.

For example, the vapor deposition method is classified into a physical vapor deposition method (PVD), and a chemical vapor deposition method (CVD).

Examples of the physical vapor deposition method include vacuum vapor deposition, electron beam vapor deposition, laser abrasion, laser abrasion MBE, MOMBE, reactive vapor deposition, ion plating, the cluster ion beam method, glow discharge sputtering, ion beam sputtering, and reactive sputtering.

Examples of the chemical vapor deposition method include thermal CVD, MOCVD, RF plasma CVD, ECR plasma CVD, photo CVD, and laser CVD.

Examples of the liquid phase deposition method include LPE, electroplating, electroless plating, and coating.

Examples of the solid phase deposition method include SPE, recrystallization, graphoepitaxy, the LB method, the sol-gel method, and the aerosol deposition (AD) method.

Among the above-listed examples, the AD method is preferable because a uniform film can be formed over a region of a relatively large area, such as an electrophotographic photoconductor, and properties of a resultant electrophotographic photoconductor are not affected.

### x-Aerosol Deposition (AD) Method-

The aerosol deposition (AD) method is a technique where particles or microparticles prepared in advance are mixed with gas to turn into aerosol, and the aerosol is ejected from a nozzle to a target on which a film is formed (substrate) to form a film. The AD method can form a film in a room temperature environment, and can form a film in a state where a crystal structure of a raw material is substantially maintained as it is. Therefore, the AD method is suitable for film formation on a photoelectric conversion device (particularly, electrophotographic photoconductor).

A method for forming a ceramic film according to the aerosol deposition method will be described.

FIG. 7 is a schematic view illustrating an aerosol deposition device. A gas cylinder 111 illustrated in FIG. 7 stores inert gas for generating aerosol. The gas cylinder 111 is connected with an aerosol generator 113 via a pipe 112a, and the pipe 112a is guided inside the aerosol generator 113. The aerosol generator 113 is loaded with a predetermined amount of particles 120, which are a material for forming a ceramic film in the present disclosure. Another pipe 112b connected with the aerosol generator 113 is connected with a jet nozzle 115 inside the film formation chamber 114. Inside the film formation chamber 114, a substrate 116 is held with a substrate holder 117 to face the jet nozzle 115. As the substrate 116, an aluminium foil (positive electrode collector) is used. An exhaust pump 118 configured to adjust the vacuum degree inside the film formation chamber 114 is connected to the film formation chamber 114 via a pipe 112c.

Although it is not illustrated, disposed is a system for moving the substrate holder 117 in the cross direction (the cross direction in the plane of the substrate holder 117 facing the jet nozzle 115 to move the jet nozzle 115 in the longitudinal direction (the longitudinal direction in the plane of the substrate holder 117 facing the jet nozzle 115). A ceramic film having a desired area can be formed on the substrate 116 by performing film formation with moving the substrate holder 117 in the cross direction and the jet nozzle 115 in the longitudinal direction.

In the step for forming the ceramic film, first, the compressed air valve 119 is closed, and the atmosphere of the area from the film formation chamber 114 to the aerosol generator 113 is vacuumed by the exhaust pump 118. Next, the gas inside the gas cylinder 111 introduced into the aerosol generator 113 via the pipe 112a by opening the compressed air valve 119, and the particles 120 are sprinkled inside the container to generate aerosol in which the particles 120 are dispersed in the gas. The generated aerosol was ejected from the jet nozzle 115 to the substrate 116 via the pipe 112b at high speed. After passing 0.5 seconds with the compressed air valve 119 opened, the compressed air valve 119 is closed for the next 0.5 seconds. Then, the compressed air valve 119 is opened again, and the opening and closure of the compressed air valve 119 is repeated with a cycle of 0.5 seconds. The flow rate of the gas from the gas cylinder 111 is set to 2 L/min, and the film formation duration is 7 hours. The degree of vacuum inside the film formation chamber 114 when the compressed air valve 119 is closed is set to about 10 Pa, and the degree of vacuum inside the film formation chamber 114 when the compressed air valve 119 is closed is set to about 100 Pa.

The ejection speed of the aerosol is controlled by the shape of the jet nozzle 115, the length of inner diameter of the pipe 112b, the internal gas pressure of the gas cylinder 111, or displacement of the exhaust pump 118 (internal pressure of the film formation chamber 114). In the case where the internal pressure of the aerosol generator 113 is set to several ten thousands Pa, the internal pressure of the film formation chamber 114 is set to several tens to several hundreds pascals, and the shape of the opening of the nozzle 115 is a circle having an inner diameter of 1 mm, for example, the ejection speed of the aerosol can be made to be several hundreds meters/second due to a difference in internal pressure between the aerosol generator 113 and the film formation chamber 114. When the internal pressure of the film formation chamber 114 is maintained from 5 Pa through 100 Pa, and the internal pressure of the aerosol generator 113 is maintained to 50,000 Pa, a ceramic film having porosity of from 5% through 30% can be formed. The average thickness of the ceramic film can be adjusted by adjusting the duration for supplying the aerosol under the above-described conditions.

The average thickness of the ceramic film is preferably from 0.1 µm through 10 µm, and more preferably from 0.5 µm through 5.0 µm.

The particles 120, the speed of which are accelerated to receive kinetic energy, in the aerosol are crushed into a photoconductor that is a substrate 116 to finely pulverize the particles with the impact energy. A ceramic film is sequentially formed on the charge-transporting layer by allowing the pulverized particles to adjoin the substrate (photoconductor) 116 and allowing the pulverized particles to adjoin one another.

The film formation is performed with a plurality of line patterns and rotations of the photoconductor drum. A ceramic film having a desired area is formed by scanning the drum holder 117 or the jet nozzle 115 in a longitudinal direction and a cross direction of a surface of the substrate (photoconductor) 116.

### Organic EL Element

Next, one example of an organic electroluminescent element (OLED) including a photoelectric conversion element that is a device of the present disclosure will be described. The descriptions above may be also applied for the embodiment of the organic EL element. If there are descriptions below associated with the organic EL element of the present embodiment, the following descriptions are prioritized.

Since a surface layer of the device (organic EL element) of the present disclosure is a ceramic film, the device (organic EL element) has excellent gas barrier properties, particularly moisture barrier properties, and has excellent durability. Since the undercoat layer includes a siloxane compound, moreover, a quality of a display image can be improved as well as more excellent durability is obtained. Since the organic EL element includes the undercoat layer including the siloxane compound, particularly, the organic EL layer having high gas permeability and low strength can be covered with a dense inorganic film, to thereby improve gas barrier properties.

FIG. 8 is a schematic cross-sectional view illustrating one embodiment of the device (organic EL element) of the present disclosure. The organic EL element 50C of the present embodiment has a laminate structure where a support 51, a negative electrode 52, an electron-injecting layer 53, an electron-transporting layer 54, a light-emitting layer 55, a hole-transporting layer 56, an undercoat layer 57, a surface layer 58, and a positive electrode 59 are disposed in this order. Note that, a reverse layer structure of an organic EL element that is advantageous in terms of durability is regarded as a standard element configuration in the present disclosure, but the present invention is not limited to this configuration.

### <Support>

In the organic EL element of the present embodiment, the support 51 may be constructed as a substrate.

The support is preferably an insulation substrate.

For example, the support may be a plastic substrate or a film substrate.

A barrier film may be disposed on the main surface 51a of the substrate 51. For example, the barrier film may be a film formed of silicon, oxygen, and carbon, or a film formed of silicon, oxygen, carbon, and nitrogen.

Examples of a material of the barrier film include silicon oxide, silicon nitride, and silicon oxynitride.

The average thickness of the barrier film is preferably 100 nm or greater but 10 µm or less.

### <Organic EL Layer>

In the organic EL element of the present embodiment, the photoelectric conversion layer may be constructed as an organic EL layer.

The organic EL layer includes, for example, a light emitting layer, and is a function part contributing to emission of the light emitting layer such as transfer of carriers and combination of carriers depending on voltage applied to the anode and the cathode.

The organic EL layer may include, for example, the electron injecting layer 53, the electron transporting layer 54, the light emitting layer 55, and the hole transporting layer 56. The organic EL layer including electrodes such as a cathode and an anode may be referred to as an organic EL layer according to circumstances.

### <Electron-injecting Layer>

The electron injecting layer 53 may be disposed as a layer that decreases obstacle to electron injection from the cathode 52 to the electron transporting layer 54 formed of an organic material having a small electron affinity.

Examples of a material used for the electron-injecting layer 53 include metal oxide including magnesium, aluminium, calcium, zirconium, silicon, titanium, or zinc, polyphenylene vinylene, hydroxyquinoline, and a naphthalimide derivative.

The average thickness of the electron-injecting layer 53 is preferably from 5 nm through 1,000 nm, and more preferably from 10 nm through 30 nm. The average thickness thereof can be measured by spectroscopic ellipsometry, using a surface roughness tester, or microscopic image analysis.

### <Electron-transporting Layer>

Examples of a low molecular weight compound used as a material of the electron-transporting layer 54 include an oxazole derivative, an oxadiazole derivative, a pyridine derivative, a quinoline derivative, a pyrimidine derivative, a pyrazine derivative, a phenanthroline derivative, a triazine derivative, a triazole derivative, an imidazole derivative, tetracarboxylic anhydride, various metal complexes (e.g., tris(8-hydroxyquinolinato) aluminium (Alq3)), and a silole derivative. The above-listed examples may be used alone or in combination. Among the above-listed examples, a metal complex, such as Alq3, and a pyridine derivative are preferable.

The average thickness of the electron-transporting layer 54 is preferably from 10 nm through 200 nm, and more preferably from 40 nm through 100 nm. The average thickness thereof can be measured by spectroscopic ellipsometry, using a surface roughness tester, or microscopic image analysis.

### <Light-emitting Layer>

The light-emitting layer 55 is a layer that emits light after generating excitons due to recombination of holes and electrons injected from the positive electrode and the negative electrode.

Examples of a polymer material for forming the light-emitting layer 55 include a pol-yaraphenylene vinylene-based compound, a polyfluorene-based compound, and a poly-carbazole-based compound.

Examples of a low molecular weight material for forming the light-emitting layer 55 include metal complexes (e.g., tris(8-hydroxyquinolinato)aluminium (Alq3), tris(4-methyl-8 quinolinolate)aluminium(III) (Almq3), 8-hydroxyquinoline zinc (Znq2), (1,10-phenanthroline)-tris-(4,4,4-trifluoro-1-(2-thienyl)-butane-1,3-dionate) europium(III) (Eu(TTA)3(phen)), and 2,3,7,8,12,13,17,18-octaethyl-21H,23H-porphine platinum(II)), metal complexes (e.g., bis[2-(o-hydroxyphenyl benzothiazole] zinc(II) (ZnBTZ2), and bis[2-(2-hydroxyphenyl)-pyridine]beryllium (Bepp2)), metal complexes (e.g., tris[3-methyl-2-phenylpyridine] iridium(III) (Ir(mpy)3)), distyrylbenzene derivatives, phenanthrene derivatives, perylene-based compounds, carbazole-based compounds, benzimidazole-based compounds, benzothiazole-based compounds, coumarin-based compounds, perinone-based compounds, oxadiazole-based compounds, quinacridone-based compounds, pyridine-based compounds, and spiro compounds. The above-listed examples may be used alone or in combination.

The average thickness of the light-emitting layer 55 is not particularly limited, but the average thickness thereof is preferably from 10 nm through 150 nm, and more preferably from 20 nm through 100 nm. The average thickness thereof can be measured by spectroscopic ellipsometry, using a surface roughness tester, or microscopic image analysis.

### <Hole-transporting Layer>

Examples of a material for forming the hole-transporting layer 56 include an oxazole derivative, an oxadiazole derivative, an imidazole derivative, a triphenylamine derivative, a butadiene derivative, 9-(p-diethylaminostyrylanthracene), 1,1-bis-(4-dibenzylaminophenyl)propane, styrylanthracene, styrylpyrazoline, phenyl-hydrazones, α-phenylstilbene derivatives, thiazole derivatives, triazole derivatives, phenazine derivatives, acridine derivatives, benzofuran derivatives, benzimidazole derivatives, and thiophene derivatives. Other examples thereof include polyaryl amine, a fluorene-aryl amine copolymer, fluorene-bithiophene copolymer, poly(N-vinylcarbazole), polyvinyl pyrene, polyvinyl anthracene, polythiophene, polyalkylthiophene, polyhexylthiophene, poly(p-phenylenevinylene), poly(thienylene vinylene), a pyrene formaldehyde resin, an ethyl carbazole formaldehyde resin, and derivatives thereof. The above-listed hole-transporting materials may be used alone or in combination, or may be used as a mixture with other compounds.

The average thickness of the hole-transporting layer 56 is preferably from 10 nm through 150 nm, and more preferably from 40 nm through 100 nm.

### <Undercoat Layer>

The undercoat layer 57 can be the same as described above. The undercoat layer 57 includes a siloxane compound. The undercoat layer 57 of the present embodiment may be constructed as a silicon hard coat.

### <Surface Layer>

The surface layer 58 can be the same as described above. The surface layer 58 is a ceramic film also in the present embodiment. As illustrated, the surface layer 58 may be formed on side surfaces of the organic EL element, but not limited to the side surface.

The ceramic film in the organic EL element and a production method thereof can be appropriately changed and applied in addition to the ceramic film and the production method described above. For example, a positive electrode may be formed on the ceramic film. The ceramic film may be formed on a negative electrode so as to embed the organic EL layer. Moreover, the ceramic film may be formed to over side surfaces of the organic EL layer etc. Disposition of the ceramic film of the present embodiment makes it possible to impart a function of gas barrier, particularly a function of moisture barrier to the organic EL element.

### <Negative Electrode>

As the negative electrode 52, a single metal element, such as Li, Na, Mg, Ca, Sr, Al, Ag, In, Sn, Zn, and Zr, or an alloy thereof may be used. LiF as an electrode protecting film may be formed on the negative electrode in the same manner as the formation of the negative electrode. In addition, ITO, IZO, FTO, and aluminium are preferably used. The sheet resistance of the negative electrode is preferably several hundreds ohms/sq. or less.

The average thickness of the negative electrode 52 is preferably from 10 nm through 500 nm, and more preferably from 100 nm through 200 nm. The average thickness thereof can be measured by spectroscopic ellipsometry, using a surface roughness tester, or microscopic image analysis.

### <Positive Electrode>

As the positive electrode 59, for example, gold, silver, aluminium, ITO, or ZnO is preferably used. When emitted light is released from the side of the positive electrode, the transmittance of the positive electrode is preferably 10% or greater. The sheet resistance of the positive electrode is preferably several hundreads ohms/sq. or less. When the positive electrode is formed by vacuum vapor deposition, a crystal resonator film thickness meter can be used. The average thickness of the positive electrode 59 is preferably from 10 nm through 1,000 nm, and more preferably from 10 nm through 200 nm. The average thickness thereof can be measured by spectroscopic ellipsometry, using a surface roughness tester, or microscopic image analysis.

### Image Forming Method and Image Forming Apparatus

The image forming method include: charging a surface of a photoconductor (a charging step); exposing the charged surface of the photoconductor to light to form an electrostatic latent image (an exposing step); developing the electrostatic latent image with a developer to form a visible image (a developing step); and transferring the visible image to a recording medium (a transferring step), where the photoconductor is the device (photoconductor) of the present disclosure.

The image forming apparatus, which is the device of the present disclosure, is an image forming apparatus including at least a photoconductor, a charging unit configured to charge a surface of the photoconductor, an exposing unit configured to expose the charged surface of the photoconductor with light to form an electrostatic latent image, a developing unit configured to develop the electrostatic latent image with a developer to form a visible image, and a transferring unit configured to transfer the visible image to a recording medium, where the photoconductor is the device (photoconductor) of the present disclosure.

The image forming method and image forming apparatus may further include other steps and other units according to the necessity. A combination of the charging unit and the exposing unit may be referred to as an electrostatic latent image forming unit.

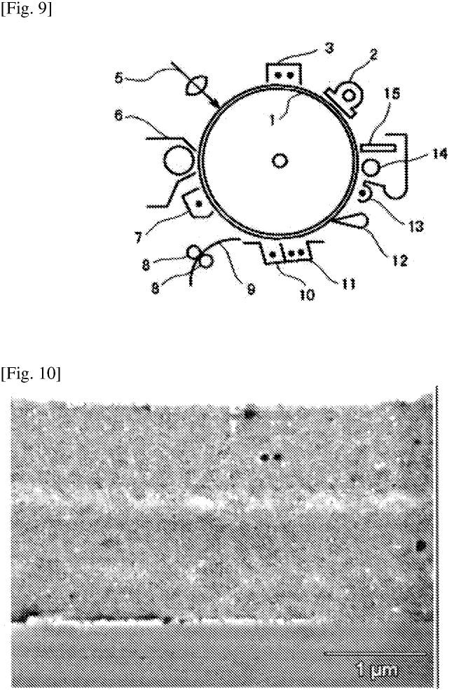

An embodiment of the image forming method and image forming apparatus of the present disclosure will be described through an example thereof, hereinafter. FIG. 9 is a schematic view for illustrating the device (image forming apparatus) of the present disclosure. A charging unit 3, an exposing unit 5, a developing unit 6, a transferring unit 10, etc. are disposed at the periphery of a photoconductor 1. First, the photoconductor 1 is evenly charged by the charging unit 3. As the charging unit 3, a corotron device, a scorotron device, a solid discharge element, a multi-stylus electrode device, a roller charging device, or a conductive brush device is used, and a system known in the art can be used.

Next, an electrostatic latent image is formed on the uniformly charged photoconductor 1 by the exposing unit 5.

As a light source of the exposing unit 5, any of general emitters, such as a fluorescent lamp, a tungsten lamp, a halogen lamp, a mercury lamp, a sodium vapor lamp, a light emitting diode (LED), a semiconductor laser diode (LD), and an electroluminescent (EL) element can be used. In order to emit only light of a desired wavelength range, moreover, various filters, such as a sharp-cut filter, a band-pass filter, a near infrared-cut filter, a dichroic filter, an interference filter, and a color temperature conversion filter, can be used.

Next, the electrostatic latent image formed on the photoconductor 1 is visualized by the developing unit 6.

Examples of the developing system for use include a one-component developing method using a dry toner, a two-component developing method using a dry toner, and a wet developing method using a wet toner.

When the photoconductor 1 is positively (negatively) charged and image exposure is performed, a positive (negative) electrostatic latent image is formed on a surface of the photoconductor. When the positive (negative) electrostatic latent image is developed with a toner (electrostatic particles) of negative (positive) polarity, a positive image is obtained. When the positive (negative) electrostatic latent image is developed with a toner (electrostatic particles) of positive (negative) polarity, a negative image is obtained.

Next, the toner image visualized on the photoconductor 1 is transferred by a transferring unit 10 to a recording medium 9 fed by a roller 8. Moreover, the pre-transfer charger 7 may be used to perform the transfer more smoothly.

As the transferring unit 10, an electrostatic transfer system using a transfer charger, a bias roller, etc.; a mechanical transfer system, such as an adhesion transfer method, and a pressure transfer method; or a magnetic transfer system can be used.

As a unit for separating the recording medium 9 from the photoconductor 1, a separation charger 11 or a separation claw 12 may be optionally used.

As other separation methods, electrostatic attraction induction separation, side-edge belt separation, top-edge griping separation, or curvature separation is used. As the separation charger 11, the charging unit can be used. In order to clean the toner remained on the photoconductor after the transferring, moreover, a cleaning unit, such as a fur brush 14, and a cleaning blade 15, can be used. In order to perform cleaning more effectively, a cleaning pre-charger 13 may be used. As other cleaning units, there are a wet system, and a magnet brush system. The above-listed systems may be used alone or in combination. Moreover, a charge-eliminating unit 2 may be used in order to eliminate the latent image on the photoconductor 1. As the charge-eliminating unit 2, a charge-eliminating lamp or a charge-eliminating charger is used. Any of the examples of the exposure light source and the charging unit can be used for the charge-eliminating unit. As other processes not performed near the photoconductor, such as paper feeding, fixing, and paper ejection, any of processes known in the art can be used.

### EXAMPLES

Examples of the present disclosure will be described hereinafter. However, the present disclosure should not be construed as being limited to these Examples. Note that, “part(s)” described below means “part(s) by mass” unless otherwise stated.

### Example 1

The following undercoat layer coating liquid was applied onto a 100 µm-thick polyester film (TEONEX Q51-A4-100 µm, obtained from TEIJIN LIMITED) by a doctor blade, followed by drying at 130° C. for 5 minutes in the following manner. The average thickness of the undercoat layer was 1 µm.

### (Undercoat Layer Coating Liquid)

Siloxane compound-containing coating material (NSC-3101, obtained from NIPPON FINE CHEMICAL CO., LTD.): 100 parts
Trimethylethoxysilane (obtained from Tokyo Chemical Industry Co., Ltd.): 3 parts

Next, a surface layer was formed on the surface of the obtained film through the AD method by means of a device as illustrated in FIG. 7.

As metal oxide used for the film formation, high-purity alumina particles (Taimicron TM-DAR, obtained from TAIMEI CHEMICALS CO., LTD.) were used.

The film formation conditions according to the AD method were as follows.

### (Film Formation Conditions)

Moisture content of the alumina particles: 0.2% or less (the measurement value obtained by Karl Fischer Moisture Titrator)
Dew point at the time charging the container with the powder: — 50° C. or lower
Aerosol gas: nitrogen gas
Aerosol gas flow rate: 12 L/min (total amount)
Degree of vacuum inside the film formation chamber: 200 Pa
Angle between the nozzle and the coating film sample: 60 degrees
Distance between the nozzle and the coating film sample: 15 mm
Coating speed: 200 mm/min
The number of coating: 6 times (3 returns)

### Example 2

A film was formed in the same manner as in Example 1, except that the film formation conditions of the surface layer according to the AD method were changed as follows.

### (Film Formation Conditions)

Moisture content of the alumina particles: 0.2% or less (the measurement value obtained by Karl Fischer Moisture Titrator)
Dew point at the time charging the container with the powder: —50° C. or lower
Aerosol gas: nitrogen gas
Aerosol gas flow rate: 5 L/min (total amount)
Degree of vacuum inside the film formation chamber: 50 Pa
Angle between the nozzle and the coating film sample: 80 degrees
Distance between the nozzle and the coating film sample: 5 mm
Coating speed: 200 mm/min
The number of coating: 6 times (3 returns)

### Comparative Example 1

A protective film was produced in the same manner as in Example 1, except that trimethylethoxysilane was not used in the undercoat layer coating liquid.

### Example 3

### -Production Example of Electrophotographic Photoconductor-

An electrophotographic photoconductor of Example 3 including an intermediate layer 207, a charge-generating layer 203, a charge-transporting layer 204, an undercoat layer 208, and a surface layer 209 formed of a metal oxide-containing layer disposed on a conductive support 201 in this order as illustrated in FIG. 6 was produced in the following manner.

### -Formation of Intermediate Layer-

The following intermediate layer coating liquid was applied onto a conductive support (external diameter: 100 mm) formed of aluminium by dip coating to form an intermediate layer. After drying at 170° C. for 30 minutes, the average thickness of the intermediate layer was 3 µm.

### (Intermediate Layer Coating Liquid)

Zinc oxide particles (MZ-300, obtained from TAYCA CORPORATION): 350 parts
3,5-di-t-butylsalicylate: 1.5 parts (TCI-D1947, obtained from Tokyo Chemical Industry Co., Ltd.)
Blocked isocyanate: 60 parts (SUMIJULE (registered trademark) 3175, solid content: 75% by mass, obtained from Sumitomo Bayer Urethane Co., Ltd.)
Solution obtained by dissolving 20% by mass of a butyral resin in 2-butanone: 225 parts (BM-1, obtained from SEKISUI CHEMICAL CO., LTD.)
2-butanone: 365 parts

### -Formation of Charge-generating Layer-

The following charge-generating layer coating liquid was applied onto the obtained intermediate layer by dip coating to form a charge-generating layer.

The average thickness of the charge-generating layer was 0.2 µm.

### (Charge-generating Layer Coating Liquid)

Y-type titanyl phthalocyanine: 6 parts
Butyral resin (S-LEC BX-1, obtained from SEKISUI CHEMICAL CO., LTD.): 4 parts
2-butanone (obtained from KANTO CHEMICAL CO., INC.): 200 parts

### -Formation of Charge-transporting Layer-

The following charge-transporting layer coating liquid 1 was applied onto the obtained charge-generating layer to form a charge-transporting layer.

The average thickness of the charge-transporting layer after drying at 135° C. for 20 minutes was 22 µm.

### (Charge-transporting Layer Coating Liquid 1)

Bisphenol Z polycarbonate: 10 parts
(PANLITE TS-2050, obtained from TEIJIN LIMITED)
Tetrahydrofuran: 80 parts
Low molecular weight charge-transporting material of the following structural formula: 10 parts

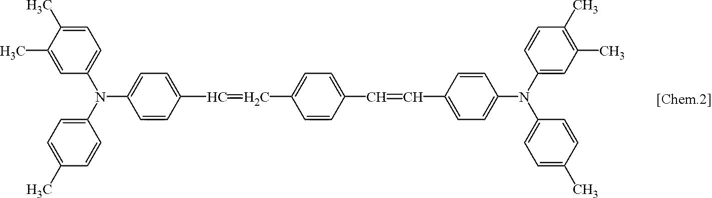

### -Formation of Undercoat Layer-

The following undercoat layer coating liquid was applied onto the obtained charge-transporting layer by ring coating, to thereby form an undercoat layer. The average thickness of the undercoat layer after drying at 120° C. for 20 minutes was 1 µm.

### (Undercoat Layer Coating Liquid)

Siloxane compound-containing coating material NSC-5506 (obtained from NIPPON FINE CHEMICAL CO., LTD.): 180 parts
Trimethylethoxysilane (obtained from Tokyo Chemical Industry Co., Ltd.): 6 parts
Polysilane (OGSOL SI-10-10, obtained from Osaka Gas Chemicals Co., Ltd.): 15 parts
Tetrahydrofuran (obtained from Mitsubishi Chemical Corporation): 180 parts

### -Formation of Metal Oxide-Containing Layer-

### (Production of Metal Oxide Powder)

Copper(I) (NC-803, obtained from NIPPON CHEMICAL INDUSTRIAL CO., LTD.) (2 kg) and 1.43 g of alumina (AA-03, obtained from SUMITOMO CHEMICAL COMPANY, LIMITED) were mixed, and the resultant mixture was heated at 1,100° C. for 40 hours to obtain copper aluminium oxide. The obtained copper aluminium oxide was ground by means of a dry disperser (DRYSTAR SDA1, obtained from Ashizawa Finetech Ltd.), and the grinding conditions were changed to obtain copper aluminium oxide powders having cumulative particle sizes D50 of 0.8 µm, 1.0 µm, 2.1 µm, 4.3 µm, and 6.6 µm. The powder particle size was measured by means of a laser diffraction/scattering particle size distribution analyzer (MT-3300EX, obtained from MicrotracBEL Corp.) at the pressure of 0.2 MPa with the dry mode.

Next, a metal oxide-containing layer was formed on the surface of the undercoat layer with the copper aluminium oxide powder (cumulative particle size D50: 4.3 µm) by the AD method.

The film formation of the metal oxide-containing layer by the AD method was performed in the following conditions.

### (Film Formation Conditions)

Moisture content of the copper aluminium oxide powder: 0.2% or less (the measurement value obtained by Karl Fischer Moisture Titrator)
Dew point at the time charging the container with the powder: —50° C.
Aerosol gas: nitrogen gas
Aerosol gas flow rate: 5 L/min (total amount)
Degree of vacuum inside the film formation chamber: 55 Pa
Angle between the nozzle and the photoconductor drum: 80 degrees
Distance between the nozzle and the photoconductor drum: 30 mm
Coating speed: 20 mm/min
Drum rotational speed: 20 rpm
The number of coating: 6 times (3 returns)

### Example 4

An electrophotographic photoconductor was produced in the same manner as in Example 3, except that the conditions for forming the undercoat layer coating liquid and the metal oxide-containing layer were changed as follows.

### (Undercoat Layer Coating Liquid)

Siloxane compound-containing coating material NSC-5506 (obtained from NIPPON FINE CHEMICAL CO., LTD.): 60 parts
Trimethylethoxysilane (obtained from Tokyo Chemical Industry Co., Ltd.): 3 parts
Polysilane (OGSOL SI-10-10, obtained from Osaka Gas Chemicals Co., Ltd.): 5 parts
Tetrahydrofuran (obtained from Mitsubishi Chemical Corporation): 60 parts

A metal oxide-containing layer was formed on the surface of the undercoat layer with the copper aluminium oxide powder (cumulative particle size D50: 2.1 µm)by the AD method.

The film formation of the metal oxide-containing layer by the AD method was performed under the following conditions.

### (Film Formation Conditions)

Moisture content of the copper aluminium oxide powder: 0.2% or less (the measurement value obtained by Karl Fischer Moisture Titrator)
Dew point at the time charging the container with the powder: —55° C.
Aerosol gas: nitrogen gas
Aerosol gas flow rate: 4 L/min (total amount)
Degree of vacuum inside the film formation chamber: 50 Pa
Angle between the nozzle and the photoconductor drum: 80 degrees
Distance between the nozzle and the photoconductor drum: 30 mm
Coating speed: 20 mm/min
Drum rotational speed: 20 rpm
The number of coating: 6 times (3 returns)

### Example 5

An electrophotographic photoconductor was produced in the same manner as in Example 4, except that the conditions for forming the metal oxide-containing layer were changed as follows.

### -Formation of Metal Oxide-Containing Layer-

### (Production of Metal Oxide Powder)

High-purity alumina particles (Taimicron TM-DAR, obtained from TAIMEI CHEMICALS CO., LTD.) (500 g) and 500 g of barium titanate (obtained from KANTO CHEMICAL CO., INC.) were mixed by Turbula Mixer, and the resultant mixture was ground by means of a dry disperser (DRYSTAR SDA1, obtained from Ashizawa Finetech Ltd.) to obtain a metal oxide mixture powder having a cumulative particle size D50 of 0.8 µm.

Next, a metal oxide-containing layer was formed on the surface of the undercoat layer with the mixture powder by the AD method.

The conditions of the film formation of the metal oxide-containing layer by the AD method were as follows.

### (Film Formation Conditions)

Moisture content of the metal oxide mixture powder: 0.2% or less (the measurement value obtained by Karl Fischer Moisture Titrator)
Dew point at the time charging the container with the powder: —55° C.
Aerosol gas: nitrogen gas
Aerosol gas flow rate: 4 L/min (total amount)
Degree of vacuum inside the film formation chamber: 50 Pa
Angle between the nozzle and the coating film sample: 80 degrees
Distance between the nozzle and the photoconductor drum: 5 mm
Coating speed: 20 mm/min
Drum rotational speed: 20 rpm
The number of coating: 6 times (3 returns)

### Comparative Example 2

An electrophotographic photoconductor was produced in the same manner as in Example 3, except that the conditions for forming the undercoat layer coating liquid and the metal oxide-containing layer were changed as follows.

### (Undercoat Layer Coating Liquid)

Siloxane compound-containing coating material NSC-5506 (obtained from NIPPON FINE CHEMICAL CO., LTD.): 60 parts
Polysilane (OGSOL SI-10-10, obtained from Osaka Gas Chemicals Co., Ltd.): 5 parts
Tetrahydrofuran (obtained from Mitsubishi Chemical Corporation): 60 parts

A metal oxide-containing layer was formed on the surface of the undercoat layer with the copper aluminium oxide powder (cumulative particle size D50: 0.8 µm)by the AD method.

The film formation of the metal oxide-containing layer by the AD method was performed under the following conditions.

### (Film Formation Conditions)

Moisture content of the copper aluminium oxide powder: 0.2% or less (the measurement value obtained by Karl Fischer Moisture Titrator)
Dew point at the time charging the container with the powder: —52° C.
Aerosol gas: nitrogen gas
Aerosol gas flow rate: 12 L/min (total amount)
Degree of vacuum inside the film formation chamber: 200 Pa
Angle between the nozzle and the photoconductor drum: 60 degrees
Distance between the nozzle and the photoconductor drum: 30 mm
Coating speed: 20 mm/min
Drum rotational speed: 20 rpm
The number of coating: 6 times (3 returns)

### Example 6

An organic EL element as illustrated in FIG. 8 was produced in the following manner. On the resin surface of the polyester film used in Example 1, a SiO₂ layer was formed as an undercoat layer, and a film of indium-tin oxide (ITO) was formed by sputtering to give a surface resistance of 15 ohms/sq. to thereby form a negative electrode 52. Next, the substrate was sequentially washed with a neutral detergent, an oxygen-based detergent, and isopropyl alcohol.

Next, sputtering was performed using ITZO as a target with introducing argon and oxygen under the vacuumed conditions of 1 x 10⁻⁴ Pa, to thereby form a 20 nm-thick electron-injecting layer 53. Subsequently, the resultant was subjected to ultrasonic cleaning with acetone and isopropyl alcohol for 10 minutes, followed by blowing nitrogen gas to dry. Thereafter, UV ozone cleaning was performed for 10 minutes.

Subsequently, tris(8-quinolinolato)aluminium (Alq3) in the thickness of 20 nm was deposited as an electron-transporting layer 54, and the compound represented by Structural Formula (B) below in the thickness of 15 nm was deposited as light-emitting layer 55 by means of a vacuum vapor deposition device.

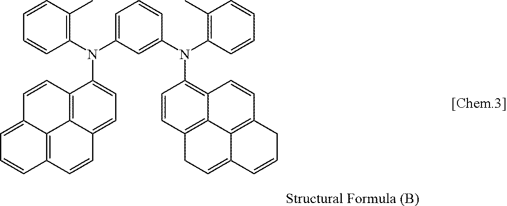

Subsequently, a hole-transporting material of Structural Formula (C) below was deposited thereon through vacuum vapor deposition, to form a hole-transporting layer 56 having the average thickness of 20 nm. In the manner as described above, an organic EL layer including the electron-injecting layer 53, the electron-transporting layer 54, the light-emitting layer 55, and the hole-transporting layer 56 was formed.

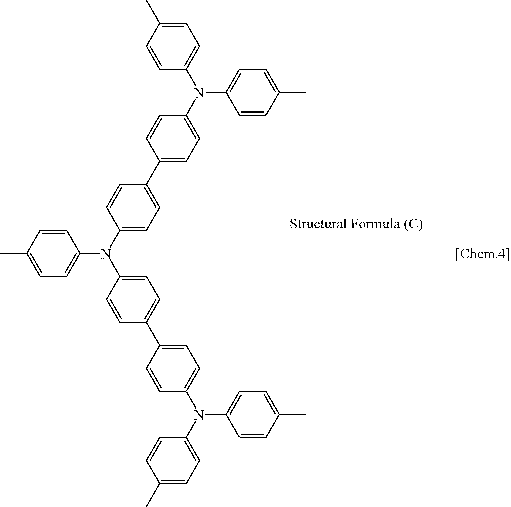

Next, a film having the average thickness of 100 nm was formed with the undercoat layer coating liquid having the following composition by inkjet printing, to thereby form an undercoat layer 57.

### (Undercoat Layer Coating Liquid)

Siloxane compound-containing coating material NSC-5506 (obtained from NIPPON FINE CHEMICAL CO., LTD.): 180 parts
Trimethylethoxysilane (obtained from Tokyo Chemical Industry Co., Ltd.): 6 parts
Polysilane (OGSOL SI-10-10, obtained from Osaka Gas Chemicals Co., Ltd.): 15 parts
Tetrahydrofuran (obtained from Mitsubishi Chemical Corporation): 100 parts
Cyclohexanone (obtained from KANTO CHEMICAL CO., INC.): 80 parts

For the inkjet printing, an inkjet head GEN3E2 obtained from Ricoh Industry Company, Ltd. was used. The drawing frequency was set to 310 Hz, and the distance between the head and the substrate was set to 1 mm. Moreover, the pulse voltage was set to 20 V. After the film formation, a vacuum dry process was performed at 120° C. for 1 hour.

Next, a film of copper aluminium oxide (CuAlO₂) having the average thickness of 50 nm was performed by the aerosol deposition method, to thereby form a surface layer 58. Moreover, a positive electrode 59 formed of an ITO film having the average thickness of 150 nm was formed by sputtering, to thereby obtain an organic EL element.

A part of each of the products of Examples 1 to 6 and Comparative Examples 1 to 2 was cut out to obtain a sample, the sample was processed to expose a smooth cross-section thereof by a focus ion beam processing device (Quanta 3D, obtained from FEI), and the cross-section was observed under an electron microscope (Ultra-55, obtained from Carl Zeiss) and an energy dispersive X-ray spectrometer (NORAN System Six, obtained from Thermo Fisher Scientific K.K.)-EDS mapping. As the observation conditions of the electron microscope, acceleration voltage of 2.0 kV, the magnification of 10,000 time, and observation with an in-lens detector for observation were set as the standard conditions. The distribution of the metal oxide in the undercoat layer was evaluated based on the observation above.

A scratch test was performed on the surface layer of each of the laminates of Examples 1 to 6 and Comparative Examples 1 to 2. The scratch test was performed by scratching to leave a mark having a scratch width of 50 µm by means of a scratch tester (CSR-2000, obtained from RHESCA CO., LTD.) with settings where a diameter of a stylus was 5 µm, the scratching speed was 10 µm/s, the excitation level was 50 µm, and the set load was 10 mN. The load at the critical point of the signal output corresponding to the friction force obtained by the scratch test was evaluated.

The results are presented in Table 1. In Table 1, the base means a layer just below the undercoat layer (a layer disposed at the opposite side to the ceramic film).

TABLE 1

| | Metal oxide distribution state in undercoat layer | Scratch evaluation [mN] |
|---|---|---|
| Ex. 1 | homogeneously distributed | 22 |
| Ex. 2 | homogeneously distributed, but a large amount thereof was present near the interface with base | 31 |
| Ex. 3 | homogeneously distributed | 23 |
| Ex. 4 | homogeneously distributed, but a large amount thereof was present near the interface with base | 33 |
| Ex. 5 | homogeneously distributed, but a large amount thereof was present near the interface with base | 35 |
| Ex. 6 | homogeneously distributed | 22 |
| Comp. Ex. 1 | could not be observed | 15 |
| Comp. Ex. 2 | could not be observed | 16 |

All the products in which the metal oxide was homogeneously distributed in the siloxane compound-containing undercoat layer or a large amount of the metal oxide was present near the interface with base had excellent results of the scratch evaluation.

### <Evaluations of Electrophotographic Photoconductor>

The following evaluations were performed on each of the above-prepared electrophotographic photoconductors of Examples 3 to 5 and Comparative Example 2. The evaluation results of each electrophotographic photoconductor are presented in Table 2.

### <Image Evaluation After NO₂ Exposure>

First, the electrophotographic photoconductor was left to stand in the NO₂ atmosphere for a certain period to allow NO₂ to be adsorbed on a surface of the electrophotographic photoconductor. As a result of researches on the conditions where adsorption sites near the surface of the electrophotographic photoconductor were saturated with NO₂ using various electrophotographic photoconductors, it was found that exposure in the camber the concentration of which was controlled to 40 ppm for 24 hours was preferable. Therefore, the exposure conditions were set to have the NO₂ concentration of 40 ppm, and the exposure duration of 24 hours.

Moreover, an image evaluation after NO₂ exposure was performed by means of a modified device of Ricoh Pro C9110 (obtained from Ricoh Company Limited) that had been modified to eliminate an initial idle process at the time of image output, using Protoner Black C9100, and using A3 size copy paper (POD gloss coat, obtained from Oji Paper Co., Ltd.) as a sheet. As an output image, a half tone image where a dot image was formed with black or white continuous pattern with 4 dots in aligned vertically and horizontally at 1,200 dpi was continuously output on 3 sheets after printing 0 sheets, 500,000 sheets, or 5,000,000 sheets of a pattern for evaluation. The dot reproduction state of the output image on the 3 sheets was observed with naked eyes and under a microscope. The results were evaluated based on the following evaluation criteria.

### -Evaluation Criteria-

5: The dot reproduction state of the output images on the 3 sheets did not change from the initial print image quality, and there was no problem.

4: The dot reproduction state of the output images on the 3 sheets was slightly inferior to the initial print image quality, but a change could not be confirmed with the naked eyes and there was no problem.

3: The dot reproduction state of the output images on the 3 sheets was slightly changed, but it was a level by which there was no problem on practical use.

2: Slight bleeding was observed in the dot reproduction state of the output images on the 3 sheet.

1: A clear change in density was observed in the dot reproduction state of the output images on the 3 sheet.

TABLE 2

| | Image evaluation |
|---|---|
| Ex. 3 | 4 |
| Ex. 4 | 5 |
| Ex. 5 | 5 |
| Comp. Ex. 2 | 3 |

All the electrophotographic photoconductor in which the metal oxide was homogeneously distributed in the siloxane compound-containing undercoat layer or a large amount of the metal oxide was present near the interface with base had excellent results of the image evaluation.

Moreover, when the amount of the metal oxide present near the interface between the plastic film or the photoconductive layer and the undercoat layer was greater than the amount of the metal oxide near the surface opposite to the interface, excellent strength and durability of the ceramic film were obtained. Moreover, the embodiment as described could be obtained by adjusting various conditions of the AD method.

### Example 7

In the manner as described above, the following undercoat layer coating liquid was applied onto a polycarbonate sheet (Technolloy C000 polycarbonate resin sheet, obtained from SUMIKA ACRYL Co., Ltd.) having a thickness of 1.0 mm by a doctor blade, and the applied coating liquid was dried at 80° C. for 20 minutes, followed by drying at 120° C. for 20 minutes. The average thickness of the undercoat layer was 3 µm.

### (Undercoat Layer Coating Liquid)

Silicone coating material (X-40-9250, obtained from Shin-Etsu Chemical Co., Ltd.): 380 parts
Catalyst (DX-9740, obtained from Shin-Etsu Chemical Co., Ltd.): 20 parts
Cyclopentanone (obtained from Tokyo Chemical Industry Co., Ltd.): 444 parts
Tetrahydrofuran (obtained from Mitsubishi Chemical Corporation): 1,556 parts

Next, a surface layer was formed on the surface of the sheet by means of a device as illustrated in FIG. 7 by the AD method.

As metal oxide used for film formation, high-purity alumina particles (Taimicron TM-DAR, obtained from TAIMEI CHEMICALS CO., LTD.) were used.

The conditions for the film formation by the AD method were as follows.

### (Film Formation Conditions)

Moisture content of the alumina particles: 0.2% or less (the measurement value obtained by Karl Fischer Moisture Titrator)
Dew point at the time charging the container with the powder: —50° C. or lower
Aerosol gas: nitrogen gas
Aerosol gas flow rate: 5 L/min (total amount)
Degree of vacuum inside the film formation chamber: 50 Pa
Angle between the nozzle and the coating film sample: 60 degrees
Distance between the nozzle and the coating film sample: 15 mm
Coating speed: 200 mm/min
The number of coating: 6 times (3 returns)

### Example 8

A sheet was produced in the same manner as in Example 7, except that the undercoat layer coating liquid was changed to the following undercoat layer coating liquid, and the conditions for forming the surface layer (metal oxide-containing layer) were changed as follows.

### (Undercoat Layer Coating Liquid)

Silicone coating material (KR-401, obtained from Shin-Etsu Chemical Co., Ltd.): 400 parts
Cyclopentanone (obtained from Tokyo Chemical Industry Co., Ltd.): 444 parts
Tetrahydrofuran (obtained from Mitsubishi Chemical Corporation): 1,556 parts

### (Film Formation Conditions)

Moisture content of the alumina particles: 0.2% or less (the measurement value obtained by Karl Fischer Moisture Titrator)
Dew point at the time charging the container with the powder: —55° C.
Aerosol gas: nitrogen gas
Aerosol gas flow rate: 12 L/min (total amount)
Degree of vacuum inside the film formation chamber: 200 Pa
Angle between the nozzle and the photoconductor drum: 60 degrees
Distance between the nozzle and the photoconductor drum: 30 mm
Coating speed: 20 mm/min
Drum rotational speed: 20 rpm
The number of coating: 6 times (3 returns)

### Example 9

An electrophotographic photoconductor was produced in the same manner as in Example 3, except that the conditions for forming the undercoat layer coating liquid and the metal oxide-containing layer were changed as follows.

### (Undercoat Layer Coating Liquid)

Silicone coating material (X-40-9250, obtained from Shin-Etsu Chemical Co., Ltd.): 76 parts
Catalyst (DX-9740, obtained from Shin-Etsu Chemical Co., Ltd.): 4 parts
Polysilane (OGSOL SI-10-40, obtained from Osaka Gas Chemicals Co., Ltd.): 20 parts
Tetrahydrofuran (obtained from Mitsubishi Chemical Corporation): 400 parts

On the surface of the undercoat layer, a metal oxide-containing layer was formed with the copper aluminium oxide powder (cumulative particle size D50: 2.1 µm) by the AD method.

The film formation of the metal oxide-containing layer was performed under the following conditions according to the AD method.

### (Film Formation Conditions)

Moisture content of the copper aluminium oxide powder: 0.2% or less (the measurement value obtained by Karl Fischer Moisture Titrator)
Dew point at the time charging the container with the powder: —50° C.
Aerosol gas: nitrogen gas
Aerosol gas flow rate: 5 L/min (total amount)
Degree of vacuum inside the film formation chamber: 50 Pa
Angle between the nozzle and the photoconductor drum: 80 degrees
Distance between the nozzle and the photoconductor drum: 30 mm
Coating speed: 20 mm/min
Drum rotational speed: 20 rpm
The number of coating: 6 times (3 returns)

### Example 10

An electrophotographic photoconductor was produced in the same manner as in Example 9, except that the conditions for forming the undercoat layer coating liquid and the metal oxide-containing layer were changed as follows.

### (Undercoat Layer Coating Liquid)

Silicone coating material (X-40-9250, obtained from Shin-Etsu Chemical Co., Ltd.): 76 parts
Catalyst (DX-9740, obtained from Shin-Etsu Chemical Co., Ltd.): 4 parts
Tetrahydrofuran (obtained from Mitsubishi Chemical Corporation): 400 parts
Charge-transporting material represented by the following structure: 20 parts

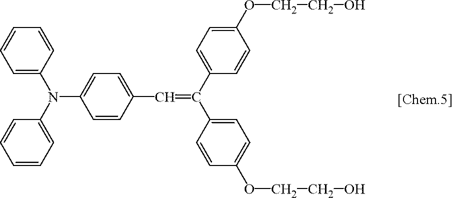 [SMILES: OCCOc1ccc(C(=Cc2ccc(N(c3ccccc3)c3ccccc3)cc2)c2ccc(OCCO)cc2)cc1]

### (Film Formation Conditions)

Moisture content of the copper aluminium oxide powder: 0.2% or less (the measurement value obtained by Karl Fischer Moisture Titrator)
Dew point at the time charging the container with the powder: —52° C.
Aerosol gas: nitrogen gas
Aerosol gas flow rate: 12 L/min (total amount)
Degree of vacuum inside the film formation chamber: 200 Pa
Angle between the nozzle and the photoconductor drum: 60 degrees
Distance between the nozzle and the photoconductor drum: 30 mm
Coating speed: 20 mm/min
Drum rotational speed: 20 rpm
The number of coating: 6 times (3 returns)

A scratch test was performed on the surface layer of each of the laminates of Examples 7 to 10. The scratch test was performed by scratching to leave a mark having a scratch width of 50 µm by means of a scratch tester (CSR-2000, obtained from RHESCA CO., LTD.) with settings where a diameter of a stylus was 5 µm, the scratching speed was 10 µm/s, the excitation level was 50 µm, and the set load was 10 mN. The load at the critical point of the signal output corresponding to the friction force obtained by the scratch test was evaluated.

The results are presented in Table 3. In Table 3, the base means a layer just below the undercoat layer (a layer disposed at the opposite side to the ceramic film).

TABLE 3

| | Metal oxide distribution state in undercoat layer | Scratch evaluation [mN] |
|---|---|---|
| Ex. 7 | homogeneously distributed | 23 |
| Ex. 8 | homogeneously distributed, but a large amount thereof was present near the interface with base | 28 |
| Ex. 9 | homogeneously distributed | 26 |
| Ex. 10 | homogeneously distributed, but a large amount thereof was present near the interface with base | 31 |

All the laminates in which the metal oxide was homogeneously distributed in the siloxane compound-containing undercoat layer had excellent results of the scratch evaluation.

### <Evaluation of Electrophotographic Photoconductor>

Evaluations that were the same evaluations performed in Example 3 were performed on each of the above-produced electrophotographic photoconductors of Examples 9 to 10. The evaluation results of each of the electrophotographic photoconductors are presented in Table 4.

TABLE 4

| | Image evaluation |
|---|---|
| Ex. 9 | 5 |
| Ex. 10 | 5 |

All the electrophotographic photoconductor in which the metal oxide was homogeneously distributed in the siloxane compound-containing undercoat layer or a large amount of the metal oxide was present near the interface with base had excellent results of the image evaluation.

Moreover, when the amount of the metal oxide present near the interface between the plastic film or the photoconductive layer and the undercoat layer was greater than the amount of the metal oxide near the surface opposite to the interface, excellent strength and durability of the ceramic film were obtained. Moreover, the embodiment as described could be obtained by adjusting various conditions of the AD method.

### REFERENCE SIGNS LIST

1: photoconductor
2: charge-eliminating unit
3: charging unit
5: exposing unit
6: developing unit
7: pre-transfer charger
8: roller
9: recording medium
10: transferring unit
11: separation charger
12: separation claw
13: cleaning pre-charger
14: fur brush
15: cleaning blade
50C: organic EL element
51: support
52: negative electrode
53: electron-injecting layer
54: electron-transporting layer
55: light-emitting layer
56: hole-transporting layer
57: undercoat layer
58: surface layer
59: positive electrode
111: gas cylinder
112a: pipe
112b: pipe
112c: pipe
113: aerosol generator
114: film formation chamber
115: jet nozzle
116: substrate (photoconductor)
117: substrate holder
118: exhaust pump
119: compressed air valve
120: particles
201: support
202: photoconductive layer
203: charge-generating layer
204: charge-transporting layer
205: undercoat layer
206: protective layer
207: intermediate layer
208: undercoat layer
209: surface layer

1. A laminate comprising:
a layer (1) including an organic material;
a layer (2) including a siloxane compound and metal oxide, where the layer (2) is in contact with the layer (1); and
a layer (3) including the metal oxide, where the layer (3) is in contact with the layer (2).

2. The laminate according to claim 1,
wherein the layer (1) and the layer (2) form an interface, and an amount of the metal oxide near the interface is greater than an amount of the metal oxide near a surface of the layer (2) opposite to the interface.

3. The laminate according to claim 1,
wherein the metal oxide includes delafossite, or perovskite, or both.

4. The laminate according to claim 1,
wherein the organic material is a charge-transporting material or a sensitizing dye.

5. The laminate according to claim 1,
wherein the siloxane compound includes the following structure: 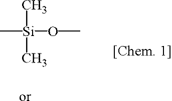 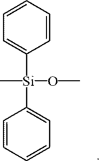
.

6. A device comprising:
a support; and
the laminate according to claim 1, disposed on the support.

7. A method for producing a laminate, the method comprising:
providing a layer (2) including a siloxane compound and metal oxide on a layer (1) including an organic material; and
providing a layer (3) including the metal oxide on the layer (2) by aerosol deposition,
wherein the laminate includes:
the layer (1);
the layer (2), where the layer (2) is in contact with the layer (1); and
the layer (3), where the layer (3) is in contact with the layer (2).

8. A method for producing a device, the method comprising providing the laminate according to claim 1 on a support.
